(19) United States
(12) Patent Application Publication
(10) Pub. No.: US 2007/0099364 A1
(43) Pub. Date: May 3, 2007

(54) Method for manufacturing a semiconductor device having a polymetal gate electrode

(76) Inventors: Takuo Ohashi, Tokyo (JP); Taishi Kubota, Tokyo (JP); Toru Miyazaki, Tokyo (JP); Shigetomi Michimata, Tokyo (JP); Satoru Yamada, Tokyo (JP)

Correspondence Address: YOUNG & THOMPSON, 745 SOUTH 23RD STREET, 2ND FLOOR, ARLINGTON, VA, 22202, US

(21) Appl. No.: 11/586,493

(22) Filed: Oct. 26, 2006

(30) Foreign Application Priority Data
Oct. 31, 2005 (JP) 2005-315975

(51) Int. Cl. H01L 21/8234; H01L 21/8242; H01L 21/336; H01L 21/3205; H01L 21/4763

(52) U.S. Cl. 438/197; 438/241; 438/287; 438/585; 438/592

(57) ABSTRACT

A method for forming a semiconductor device having a polymetal gate electrode includes the steps of forming a gate oxide film on a silicon substrate, forming a polysilicon film and a tungsten film on the gate oxide film, patterning the polysilicon film and tungsten film, and thermally oxidizing the polysilicon film in an oxidizing atmosphere including water and hydrogen at a substrate-surface temperature of 850 degrees C. and a water content of 7% to 20%.

### BACKGROUND OF THE INVENTION

(a) Field of the Invention

The present invention relates to method for manufacturing a semiconductor device having a polymetal gate electrode and, more particularly, to the improvement in a process for forming a polymetal gate electrode in a semiconductor device.

(b) Description of the Related Art

A polymetal gate electrode including a polysilicon layer and a high-melting-point metal layer is used in a semiconductor device, such as a DRAM device, to achieve a higher-speed signal transmission and a higher device integration.

FIGS. 1 to 4 show a typical process for manufacturing a DRAM device including CMOSFETs having the polymetal gate electrode. The polymetal gate electrode shown therein is known as a dual-type polymetal gate electrode including a p-type gate electrode in pMOSFETs and an n-type gate electrode in nMOSFETs.

As shown in FIG. 1, a shallow-isolation trench 12 including therein a silicon oxide film is first formed on a silicon substrate 11, thereby isolating the silicon substrate 11 into a pMOS area 10A and an nMOS area 10B. Phosphor and boron are then implanted for doping the pMOS area 10A and nMOS area 10A, respectively. Subsequently, a heat treatment is performed to diffuse and activate these dopants in the respective areas, thereby forming n-well 13 and p-well 14 in the pMOS area 10A and nMOS area 10A, respectively. A thin oxide film 15a is then formed on the entire area of the silicon substrate 11 including the shallow-isolation trench 12.

An amorphous silicon film is then deposited using a chemical vapor deposition (CVD) technique, followed by selectively implanting boron and phosphor into the amorphous silicon film of the pMOS area 10A and nMOS area 10B, respectively. A heat treatment is then performed to diffuse and activate these dopants. This heat treatment also polycrystallizes the amorphous silicon film to form a p-type polysilicon film 16a in the pMOS area 10a and an n-type polysilicon film 16b in the nMOS area 10B. A tungsten film 17 is then deposited thereon by sputtering.

A silicon nitride film 18 is then deposited using a CVD technique, followed by patterning thereof by using a photolithographic and etching technique, to thereby obtain the structure shown in FIG. 1A. Thereafter, the tungsten film 17 and polysilicon film 16 are patterned by a dry etching process using the patterned silicon nitride film 18 as an etching mask. This process provides a gate electrode 19 including the p-type polysilicon film 16a and tungsten film 17 formed on the oxide film 15a in the pMOS area 10A, and a gate electrode 20 including the n-type polysilicon film 16b and tungsten film 17 on the oxide film 15a in the nMOS area 10B, as shown in FIG. 2.

A thermal oxidation treatment is then conducted on the surface of the silicon substrate 11 and sidewall of the polysilicon film 16 for the purpose of remedying the damages of the oxide film 15a etc. caused by the dry etching process. The thermal oxidation treatment is performed as a wet-hydrogen thermal oxidation process in an oxidizing atmosphere including water and hydrogen. The wet-hydrogen thermal oxidation process allows the polysilicon film 16 to be oxidized selectively from the tungsten film 17. The water concentration in the wet-hydrogen thermal oxidation is set within a range between several percents and several tens of percents.

The thermal oxidation as described above remedies the thickness of the oxide film 15a, and forms a sidewall oxide film 21 on the polysilicon film 16. The thermal oxidation also allows a portion of the polysilicon film 16 adjacent to the oxide film 15a to be gradually oxidized from edges of the gate electrodes 19, 20 whereby a bird-beak oxide film 22 is formed on the edges of the gate electrodes, the bird-beak oxide film 22 having a base portion aligned with the edges of the gate electrode and a tip portion directed to the center of the gate electrodes 19, 20, as shown in FIG. 3. The bird-beak oxide film 22 improves the withstand voltage of the oxide film 15a near the edges of the gate electrodes 19, 20 at which the electric field is higher than the central area thereof, so long as the bird-beak oxide film 22 has a suitable thickness.

In general, the wet-hydrogen thermal oxidation is conducted at a relatively low substrate-surface temperature of around 750 degrees C. This temperature provides a moderately advancing oxidation to achieve a desired thickness of base portion of the bird-beak oxide film 22.

After the thermal oxidation process, boron is selectively implanted into the pMOS area 10A through the oxide film 15a by using the silicon nitride film 18 as a mask, thereby forming p-type lightly-doped source/drain regions 23 in the surface portion of the n-well 13 on both sides of the gate electrode 19. Subsequently, phosphor is implanted into the silicon substrate 11 of the nMOS area 10B through the oxide film 15a by using the silicon nitride film 18 as a mask, thereby forming n-type lightly-doped source/drain regions 24 in the surface portion of the p-well 14 on both sides of the gate electrode 20.

A silicon nitride film is then deposited using a CVD technique on the entire area, followed by etch-back thereof to form a sidewall nitride film 25 on the gate electrodes 19, 20. The oxide film 15a exposed from the gate electrodes 19, 20 is then removed to configure the gate oxide film 15.

Subsequently, boron is selectively implanted into the silicon substrate 11 of the pMOS area 10A by using the silicon nitride film 18 and sidewall nitride film 25 as a mask, thereby forming p-type heavily-doped source/drain regions 26 in the surface portion of the n-well 13 encircling the p-type lightly-doped source/drain regions 23. Further, phosphor is selectively implanted into the silicon substrate 11 of the nMOS area 10B by using the silicon nitride film 18 and sidewall nitride film 25 as a mask, thereby forming n-type heavily-doped regions in the surface portion of the p-well 14 encircling the n-type lightly-doped source/drain regions 24, as shown in FIG. 4. Thereafter, known processes are used for forming contact plugs, interconnections, insulation films etc. to obtain a product semiconductor device.

A conventional semiconductor device having the polymetal gate electrode structure is described in Patent Publication JP-2004-022959A, for example.

It was confirmed in our experiments that the wet-hydrogen thermal oxidation process incurs a problem wherein the bird-beak oxide film has an excessively longer tip to vary the threshold voltage of the MOSFETs. The excessively longer tip results from the fact that ingress of water into the gate oxide film during the wet-hydrogen thermal oxidation process increases the oxidation rate in the gate insulation film. Thus, the ingress of water increases the area of the bird-beak oxide film having a relatively larger thickness and thus degrades the sub-threshold characteristic of the MOSFETs.

The term “sub-threshold characteristic” as used herein generally means the switching characteristic of a MOSFET near the threshold voltage thereof, and the current flowing at the threshold voltage is referred to as a sub-threshold current. A MOSFET having a higher gradient of the sub-threshold current with respect to the gate voltage is preferable due to a superior switching characteristic involving a smaller leakage current. Sub-threshold factor (s-factor) is the reciprocal of the gradient of the sub-threshold current with respect to the gate voltage, and thus a smaller s-factor is preferable because it means a higher gradient of the sub-threshold current with respect to the gate voltage.

A longer tip of the bird-beak oxide film having a relatively larger thickness generally degrades the s-factor, wherein the s-factor depends on the gate length in which the bird-beak oxide film is formed, to thereby degrade the modeling accuracy or design accuracy of the MOSFETs.

### SUMMARY OF THE INVENTION

In view of the above problems in the conventional technique, it is an object of the present invention to provide a method for manufacturing a semiconductor device having a polymetal gate electrode, which is capable of forming a bird-beak oxide film having a suitable thickness and suppressing occurrence of an excessively longer tip thereof, in order for improving the modeling accuracy of the MOSFETs by preventing the gate length dependency of the s-factor.

The present invention provides a method for manufacturing a semiconductor device having a polymetal gate electrode, the method including: forming a gate insulation film on a silicon substrate; forming consecutively a polysilicon film and a tungsten film on the gate insulation film; patterning the polysilicon film and tungsten film; and thermally oxidizing the polysilicon film in an oxidizing atmosphere including water and hydrogen at a substrate-surface temperature of 850 degrees C. or above and a water content of 7% to 20%.

In accordance with the method of the present invention, the thermal oxidizing process performed at a substrate-surface temperature of 850 degrees C. or above and a water content of 7% to 20% in combination provides a bird-beak oxide film having a suitable thickness and a smaller length at which the s-factor in the MOSFETs does not substantially have a gate length dependency. This provides a suitable accuracy for modeling or designing the MOSFETs.

In the present invention, the substrate-surface temperature of 850 degrees C. or above suppresses degradation of the withstand-voltage performance of the gate oxide film, whereas the water content of 20% or below suppresses oxidation of the tungsten film. The term substrate-surface temperature as used in this text means the temperature of the topmost layer of the current layer structure of the semiconductor device.

The above and other objects, features and advantages of the present invention will be more apparent from the following description, referring to the accompanying drawings.

### BRIEF DESCRIPTION OF THE DRAWINGS

FIG. 1 is a sectional view of a semiconductor device in a step of fabrication thereof.

FIG. 2 is a sectional view of the semiconductor device of FIG. 1 in a subsequent steps of fabrication thereof.

FIG. 3 is a sectional view of the semiconductor device of FIG. 2 in a subsequent steps of fabrication thereof.

FIG. 4 is a sectional view of the semiconductor device of FIG. 3 in a subsequent steps of fabrication thereof.

FIG. 5 is a graph showing the results of experiments.

FIGS. 6A and 6B are graphs showing the relationship between the edge thickness of the oxide film and the substrate-surface temperature and between the edge thickness of the oxide film and the water content, respectively, in a wet-hydrogen thermal oxidation process.

FIG. 7 is a graph showing the relationship between the range of variation in the threshold voltage (Vt) and the substrate-surface temperature in the wet-oxidation thermal oxidation process.

FIG. 8 is a graph showing the relationship between the amount of contamination and the water content in the wet-hydrogen thermal oxidation process.

### PREFERRED EMBODIMENT OF THE INVENTION

Before describing a preferred embodiment of the present invention, the principle of the present invention will be described with reference to the experiments conducted by the present inventors, for a better understanding of the present invention.

A group of preliminary experiments was conducted while changing the substrate temperature (i.e., substrate-surface temperature) and water content in the wet-hydrogen thermal oxidation (referred to as WHTO hereinafter) process, in order for investigating the conditions for suppressing the excessively longer tip of the bird-beak oxidation film. The results of the preliminary experiments revealed that a short-time WHTO process conducted at a substrate temperature of 850 degrees C., which is significantly higher than the ordinary substrate temperature of 750 degrees C. in the conventional WHTO process conducted for a relatively longer time length, provides a suitable thickness of the bird-beak oxide film and suppresses the excessively longer tip.

The high-temperature and short-time WHTO process is preferably performed using a lamp annealer, which raises the substrate temperature at a rate as high as 50 degrees C. per second or above and thus suppresses excessive oxidation effected during the temperature rise by the lamp annealer.

The inventors further conducted the following first through fifth experiments using the lamp annealer, thereby investigating the optimum combination of the range of substrate-surface temperature and the water content in the WHTO process.

The first experiment was such that the substrate temperature and water content in the WHTO process were varied and the length of the bird-beak oxide film was investigated together with the associated gate length dependency of the s-factor of the MOSFET. The first experiment revealed that the length of the tip of the bird-beak oxide film increases together with a rise of the substrate-surface temperature or an increase of the water content in the WHTO process.

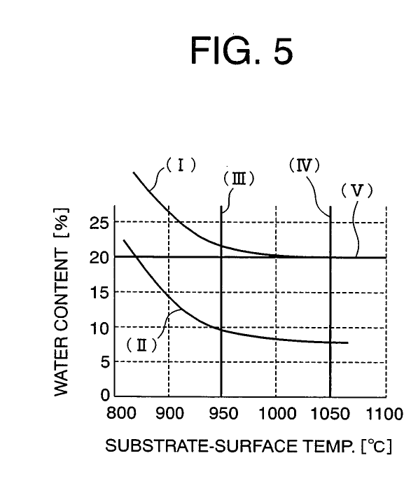

FIG. 5 shows a curve (I) found in the first experiment, wherein the curve (I) divides the coordinate plane defined by the substrate-surface temperature plotted on abscissa and the water content plotted on ordinate into two areas: a top-right area in which the s-factor had a gate length dependency, and a bottom-left area in which the s-factor had substantially no gate length dependency. The other curve (II), substrate-surface temperatures (III) and (IV) and water content (V) shown in FIG. 5 will be described hereinafter.

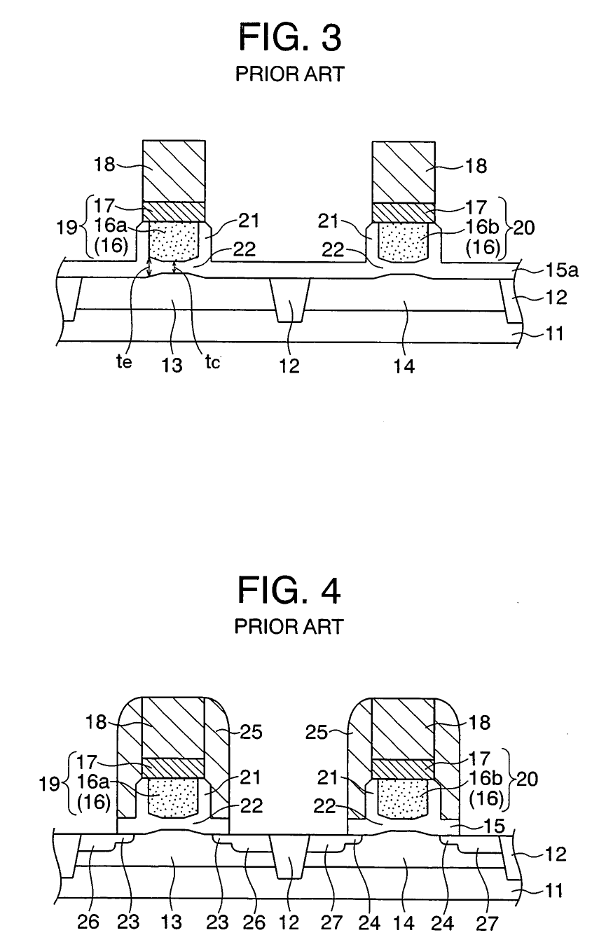

The second experiment was such that the thickness of the oxide film 15a at the edges of the gate electrodes 19, 20 (FIG. 3) is measured as an edge thickness (te) of the bird-beak oxide film 22. It is preferable that the edge thickness (te) be larger than the thickness (tc: a central thickness as shown in FIG. 3) of the oxide film 15a at the center of the gate electrodes 19, 20, in the view point of a higher overall withstand voltage of the oxide film 15a, which is applied with a higher electric field at the edges of the gate electrodes 19, 20 than the center thereof.

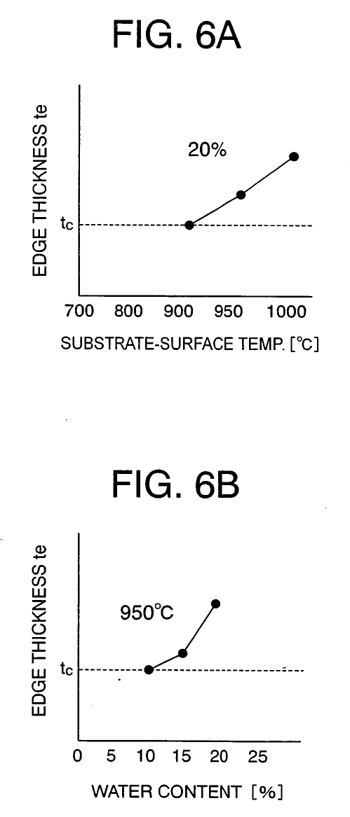

FIG. 6A shows the substrate-surface temperature dependency of the edge thickness (te) in the case of a water content of 20%. In FIG. 6A, the edge thickness (te) increases together with a rise of the substrate-surface temperature from 900 degrees C., at which the edge thickness (te) is substantially equal to the central thickness (tc).

FIG. 6B shows the water content dependency of the edge thickness (te) in the case of a substrate-surface temperature of 950 degrees C. The edge thickness (te) increases together with an increase of the water content from 10%, at which the edge thickness (te) is substantially equal to the central thickness (tc) as shown in FIG. 6B.

The second experiment was conducted further for a variety of combinations of substrate-surface temperature and water content, thereby finding a curve (II) shown in FIG. 5, on which the edge thickness (te) is equal to the central thickness (tc).

The third experiment was such that the degree of the sharpness of the edges of the polysilicon film 16 was investigated, with the substrate-surface temperature in the WHTO process being varied. It is to be noted that the sharpness of the edges of the polysilicon film degrades the withstand-voltage performance of the gate oxide film, and thus round edges of the polysilicon film are desired. The third experiment revealed that the rise of the substrate-surface temperature allowed the edges of the polysilicon film to have a round corner, providing a critical substrate-surface temperature (III) shown in FIG. 5, above which the round edges of the polysilicon film allowed the gate oxide film to have a suitable withstand-voltage performance.

The fourth experiment was such that the range of variation of the threshold voltage Vt of the pMOS FET was investigated, with the substrate-surface temperature and water content being varied and fixed at 20%, respectively, in the WHTO process. It was found in the polysilicon film doped with boron that the doped boron penetrates through the gate oxide film to diffuse toward the silicon substrate upon applying a higher substrate-surface temperature in the WHTO process. This causes a larger range of variation in the threshold voltage.

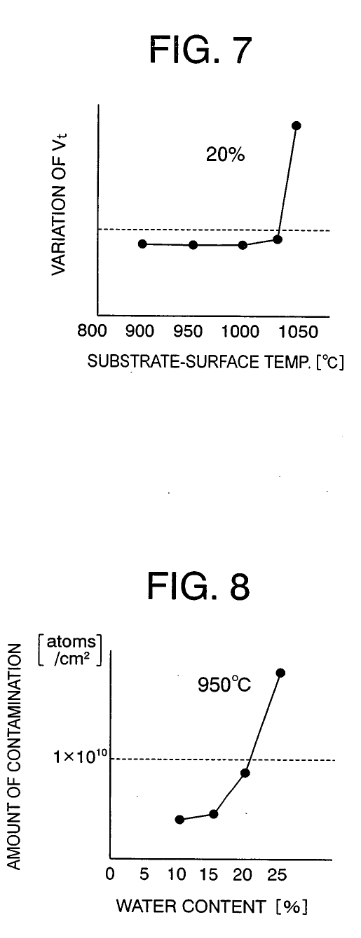

The results of the fourth experiment are shown in FIG. 7, wherein the threshold voltage Vt is relatively stable at substrate-surface temperatures below 1050 degrees C., and abruptly increases at substrate-surface temperatures above 1050 degrees C. This is considered due to the above boron penetration. In FIG. 7, the dotted line indicates the maximum threshold voltage specified by the product standard. The results of the fourth experiment are also shown at the substrate-surface temperature (IV) of 1050 degrees C. in FIG. 5.

The fifth experiment was such that the amount of contamination was investigated on the wafer surface, with the water content and the substrate-surface temperature being varied and fixed at 950 degrees C., respectively, in the WHTO process. The results shown in FIG. 8 reveal that the amount of contamination abruptly increases at water contents exceeding 20%, above which the amount of contamination exceeds 1×10¹⁰ atoms/cm², for which the semiconductor device is considered to have an inferior reliability.

Based on the results of the first through fifth experiments, the method of the present invention employs a substrate-surface temperature of 850 degrees C. or above, and a water content between 7% and 20% inclusive of both in the WHTO process. This method suppresses contamination by metals, provides a suitable thickness of the bird-beak oxide film, and suppresses the longer tip of the bird-beak oxide film and the sharp edges of the polysilicon film.

In addition, a substrate-surface temperature of 1050 degrees C. or below, if employed, suppresses penetration of boron dopant from the polysilicon film of the gate electrode toward the silicon substrate.

A substrate-surface temperature of 950 degrees C. or above and a water content of 9% or below are preferably employed for obtaining a suitable thickness of the bird-beak oxide film and round edges of the polysilicon film in the gate electrode, to thereby improve the withstand-voltage performance of the gate oxide film. In a more preferable configuration, combination of a substrate-surface temperature of 1000 degrees C. or above and a water content of 8% or above further suppresses the sharpness of the edges of the polysilicon film.

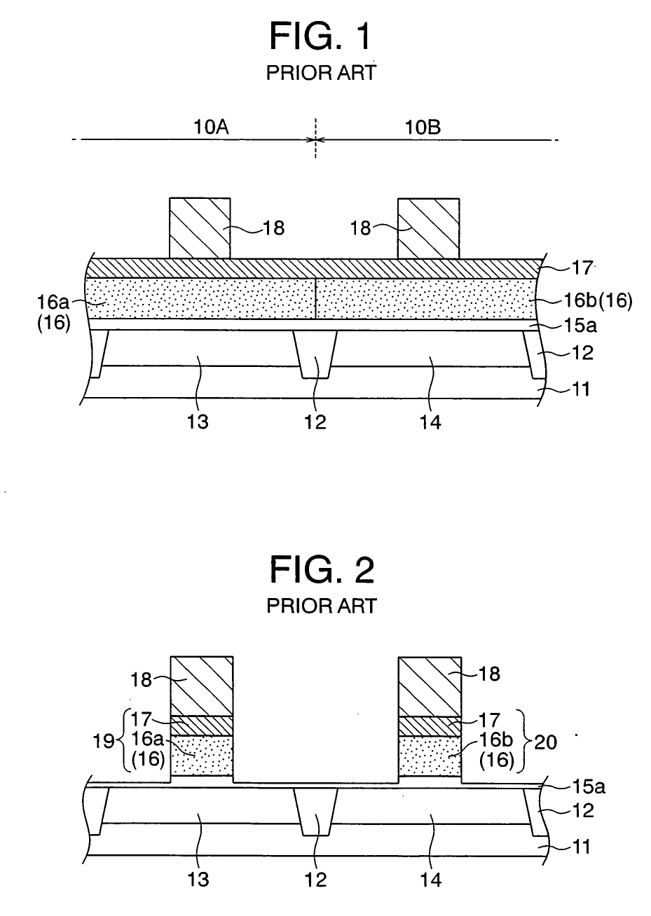

Now, a method according to an embodiment of the present invention will be described with reference to accompanying drawings. The semiconductor device manufactured by the method of the present embodiment is a CMOS device having a dual-type polymetal gate electrode. The method of the present embodiment is similar to the conventional technique described with reference to FIGS. 1 to 4 except for the conditions of the thermal oxidation using the WHTO process. Thus, the method of the present embodiment will be described again with reference to FIGS. 1 to 4.

A shallow-isolation trench 12 is first formed in the surface portion of a silicon substrate 11, to thereby isolate the silicon substrate 11 into a pMOS area 10A and an nMOS area 10B. Phosphor and boron are then implanted into the pMOS area 10A and the nMOS area 10B, respectively. Subsequently, a heat treatment is performed to diffuse and activate the implanted dopants, to form n-well and p-well in the pMOS area 10A and nMOS area 10B, respectively. A thin oxide film 15a is then formed on the silicon substrate 12.

Subsequently, an amorphous silicon film is deposited using a CVD technique, followed by implanting boron and phosphor into the amorphous silicon film of the pMOS area 10A and nMOS area 10B, respectively. Another heat treatment is then performed to diffuse and activate these dopants. This heat treatment also polycrystallizes the amorphous silicon film, to thereby provide a p-type polysilicon film 16a in the pMOS area 10A and an n-type polysilicon film 16b in the nMOS area 10B. A tungsten film 17 is then deposited thereon by sputtering.

Subsequently, a silicon nitride film 18 is formed using a CVD technique, and patterned using a photolithographic and etching technique, to obtain the structure shown in FIG. 1. Thereafter, the tungsten film 17 and polysilicon film 16 are patterned by a dry etching process using the patterned silicon nitride film 18 as an etching mask, thereby providing a gate electrode 19 including the p-type polysilicon film 16 Pa and tungsten film 17 in the pMOS area 10A, and a gate electrode 20 including the n-type polysilicon 16b and tungsten film 17 in the nMOS area 10B, as shown in FIG. 2.

Subsequently, a WHTO process is conducted to thermally oxidize the surface of the silicon substrate 11 and the sidewall of the polysilicon film 16. The WHTO process uses a lamp anneal treatment under the conditions of substrate-surface temperature of 1000 degrees C. and water content of 15%, while maintaining the 1000 degrees C. for 10 seconds. The thermal treatment remedies the original thickness of the oxide film 15a, and oxidizes the exposed surface of the polysilicon film 16, thereby forming a 3.0-nm-thick sidewall oxide film 21 on the polysilicon film 16 and a bird-beak oxide film 22 on the edges of the polysilicon film 16, as shown in FIG. 3.

Boron is then selectively implanted through the oxide film 15a into the pMOS area 10A by using the silicon nitride film 18 in the pMOS area 10A as a mask. This provides p-type lightly-doped source/drain regions 23 in the surface portion of the n-well 13 on both sides of the gate electrode 19. Thereafter, phosphor is selectively implanted through the oxide film 15a into the nMOS area 10B by using the silicon nitride film 18 in the nMOS area 10B as a mask. This provides n-type lightly-doped source/drain regions 24 in the surface portion of the p-well 14 on both sides of the gate electrode 20.

Subsequently, a silicon nitride film is deposited on the entire surface by using a CVD process, followed by etch back thereof to configure sidewall nitride film 25 on the gate electrodes 19, 20. The exposed portion of the oxide film 15a is then removed to configure a gate insulation film 15.

Subsequently, boron is selectively implanted into the silicon substrate 11 of the pMOS area 10A by using the silicon nitride film 18 and the sidewall nitride film 25 as a mask. This provides p-type heavily-doped source/drain regions 26 in the surface portion of the n-well 13 encircling the p-type lightly-doped source/drain regions 23. Phosphor is then selectively implanted into the nMOS area 10B by using the silicon nitride film 18 and sidewall oxide film 25 in the nMOS area 10B as a mask. This provides n-type heavily-doped source/drain regions 27 in the surface portion of the p-well 14 encircling the n-type lightly-doped source/drain regions 24. Other interconnects, contact plugs and insulation films are formed using known techniques to obtain a product semiconductor device.

In the present embodiment, combination of the substrate-surface temperature and water content is maintained at the bottom-left area defined by the curve (I) shown in FIG. 5, to suppress the length of the bird-beak oxide film 22 to the extent at which the s-factor of the MOSFETs does not substantially have a gate length dependency. This improves the modeling accuracy of the MOSFETs. In addition, the above combination is also maintained at the top-right area defined by the curve (II), thereby allowing the edge thickness (te) of the bird-beak oxide film 22 to be larger than the central thickness (tc) thereof. This improves a withstand property of the gate oxide film.

In the above embodiment, the substrate-surface temperature of 950 degrees C. or above in the WHTO process suppresses the sharpness of edges of the polysilicon film 16a, 16b to the extent that maintains a sufficient withstand property of the oxide film 15a.

The WHTO process conducted at a substrate-surface temperature of 1050 degrees C. or below suppresses penetration of the boron dopant in the polysilicon film 16a through the gate oxide film, to suppress variation of the threshold voltage of the pMOSFETs. The WHTO process using a water content of 20% or below suppresses oxidation of the tungsten film 17 to a desired range, to thereby suppress increase of the resistance of the gate electrodes 19, 20 caused by contamination of the gate electrodes by metals.

Since the above embodiment is described only for an example, the present invention is not limited to the above embodiment and various modifications or alterations can be easily made therefrom by those skilled in the art without departing from the scope of the present invention. For example, the gate insulation film is not limited to a gate oxide film.

What is claimed is:

1. A method for manufacturing a semiconductor device having a polymetal gate electrode, said method comprising consecutively:
forming a gate insulation film on a silicon substrate;
forming consecutively a polysilicon film and a tungsten film on said gate insulation film;
patterning said polysilicon film and tungsten film; and
thermally oxidizing said polysilicon film in an oxidizing atmosphere including water and hydrogen at a substrate-surface temperature of 850 degrees C. or above and a water content of 7% to 20%.

2. The method according to claim 1 further comprising, prior to said patterning, doping said polysilicon film with boron, wherein said substrate-surface temperature is equal to or below 1050 degrees C.

3. The method according to claim 1, wherein said thermally oxidizing includes raising the temperature of a substrate surface from a room temperature to said specified substrate-surface temperature at a rate of 50 degrees C. per second.

4. The method according to claim 3, wherein said raising the temperature is performed by a lamp annealer.

5. The method according to claim 1, wherein said substrate-surface temperature is equal to or higher than 950 degrees C, and said water content is equal to or higher than 9%.

6. The method according to claim 1, wherein said specified substrate-surface temperature is equal to or above 1000 degrees C., and said water content is equal to or lower than 8%.
